(19) United States
(12) Patent Application Publication
(10) Pub. No.: US 2026/0031180 A1
(43) Pub. Date: Jan. 29, 2026

(54) USER-ENABLED TEST MODE PATTERNS

(71) Applicant: Micron Technology, Inc., Boise, ID (US)

(72) Inventors: Gianluca Coppola, Liveri (NA) (IT); Angelo Sergio, Concorezzo (MB) (IT); Marco Lorenzo Valerio Tagliaferri, Lomagna (LC) (IT); José Maria De Matos Cortes Antunes Calcada, Monza (MB) (IT); Gennaro Schettino, Casamicciola Terme (NA (IT)

(21) Appl. No.: 19/273,965

(22) Filed: Jul. 18, 2025

Related U.S. Application Data
(60) Provisional application No. 63/675,703, filed on Jul. 25, 2024.

(51) Int. Cl. G11C 29/56

(52) U.S. Cl. CPC G11C 29/56004; G11C 29/56012; G11C 29/56016; G11C 2029/5606

(57) ABSTRACT

Methods, systems, and devices for user-enabled test mode patterns are described. A host system may transmit a command to enable transmission of test signals by a memory system according to a test pattern. The host system may determine the test pattern and parameters for transmission of the test signals based on a capability of the memory system. The memory system may receive the command to transmit the test signals according to multiple parameters, including the test pattern, associated with transmission of the test signals. The parameters may include a speed, gear, rate, clock, mode, lane, hold-off time, scrambling mode, time duration, password, or any combination thereof. The memory system may verify a capability to transmit the test signals in accordance with the parameters and transmit a confirmation message to the host system. The memory system may transmit, in accordance with the parameters and transmitting the confirmation message, the test signals.

### CROSS REFERENCE

The present application for patent claims priority to U.S. Patent Application No. 63/675,703 by Coppola et al., entitled “USER-ENABLED TEST MODE PATTERNS,” filed Jul. 25, 2024, which is assigned to the assignee hereof, and which is expressly incorporated by reference in its entirety herein.

### TECHNICAL FIELD

The following relates to one or more systems for memory, including user-enabled test mode patterns.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports user-enabled test mode patterns in accordance with examples as disclosed herein.

FIGS. 2 and 3 show examples of flow diagrams that support user-enabled test mode patterns in accordance with examples as disclosed herein.

FIG. 4 shows a block diagram of a memory system that supports user-enabled test mode patterns in accordance with examples as disclosed herein.

FIG. 5 shows a block diagram of a host system that supports user-enabled test mode patterns in accordance with examples as disclosed herein.

FIGS. 6 and 7 show flowcharts illustrating a method or methods that support user-enabled test mode patterns in accordance with examples as disclosed herein.

### DETAILED DESCRIPTION

To ensure efficient communication between a memory system and a host system, the memory system and the host system may perform timing and signal analysis. For example, the memory system and the host system may perform timing and signal analysis using a pre-defined pattern, such as a Compliant Jitter Tolerance Pattern (CJTPAT) or a Compliant Random Pattern (CRPAT), to identify transmitter jitter, identify worst-case timings, among other communication parameters. In such cases, the memory system may be loaded with firmware (e.g., engineering firmware) to enable transmission of the test pattern from the memory device to the host system. However, loading firmware onto the memory system to enable the timing and signal analysis may reduce the security of the memory system (e.g., provide increased risk by exposing the memory system to attacks), reduce flexibility of a user of the memory system 110, among other disadvantages.

As described herein, the host system may transmit a command to enable transmission of test signals from the memory system according to a test pattern. For example, the host system may determine the test pattern and parameters for transmission of the test signals based on (e.g., according to) a capability of the memory system. Based on determining the test pattern and associated parameters, the host system may transmit the command indicating for the memory system to transmit test signals according to the determined test pattern and configured parameters. In such examples, the parameters may include a speed, gear, rate, clock, mode, lane, hold-off time, scrambling mode, time duration, password, or any combination thereof.

Accordingly, in response to receiving the command, the memory system may confirm (e.g., verify) that the memory system is capable of transmitting the test signals using the parameters and transmit a confirmation message to the host system. Based on transmitting the confirmation message, the memory system may transmit the test signals using the indicated test pattern and according to the received parameters. By enabling the test pattern configuration by the host system, the techniques described herein may support increased memory system debugging capabilities at the user side, provide increased flexibility at the host and memory systems, reduce the security risk associated with loading firmware onto the memory system, among other advantages.

In addition to applicability in memory systems as described herein, techniques for configuring test signaling by a memory system via a host system may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by enabling a user to configure and enable test mode signaling, which may improve user experience, among other benefits. For example, enabling the test mode signaling configured by the user may increase a debugging capability for a user of the host system.

Features of the disclosure are illustrated and described in the context of systems, devices, and circuits. Features of the disclosure are further illustrated and described in the context of flow diagrams and flowcharts.

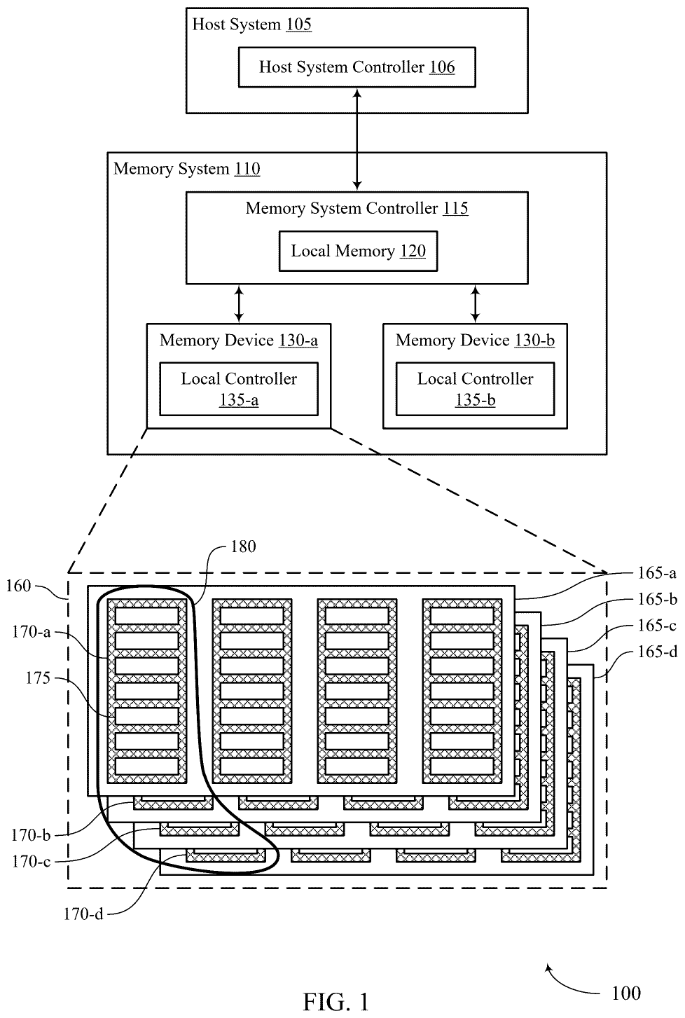

FIG. 1 shows an example of a system 100 that supports user-enabled test mode patterns in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b. A local controller 135 may be or include a microcontroller, special purpose logic circuitry (e.g., a field programmable gate array (FPGA), an application specific integrated circuit (ASIC), a digital signal processor (DSP)), or any other suitable processor or processing circuitry.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, a memory system 110 may utilize a memory system controller 115 to provide a managed memory system that may include, for example, one or more memory arrays and related circuitry combined with a local (e.g., on-die or in-package) controller (e.g., local controller 135). An example of a managed memory system is a managed NAND (MNAND) system.

As described herein, the host system 105 may transmit a command to enable transmission of test signals by the memory system 110 according to a test pattern. For example, the host system 105 may determine the test pattern and parameters for transmission of the test signals based on a capability of the memory system 110. That is, a user of the host system 105 may configure performance of timing and signal analysis by providing one or more inputs to the host system 105 resulting in transmission of a command, to the memory system 110, to transmit test signals according to a configured test pattern. The memory system 110 may receive the command to transmit the test signals according to the test pattern, among multiple parameters associated with transmission of the test signals. The parameters may include a speed, gear, rate, clock, mode, lane, hold-off time, scrambling mode, time duration, password, or any combination thereof. The memory system 110 may confirm or verify a capability to transmit the test signals in accordance with the parameters and, after verifying the capability, transmit a confirmation message to the host system. The memory system 110 may transmit, in accordance with the parameters and with transmitting the confirmation message, the test signals. By enabling the test pattern configuration by the host system 105, techniques described herein may support increased memory system 110 debugging capabilities at the user side.

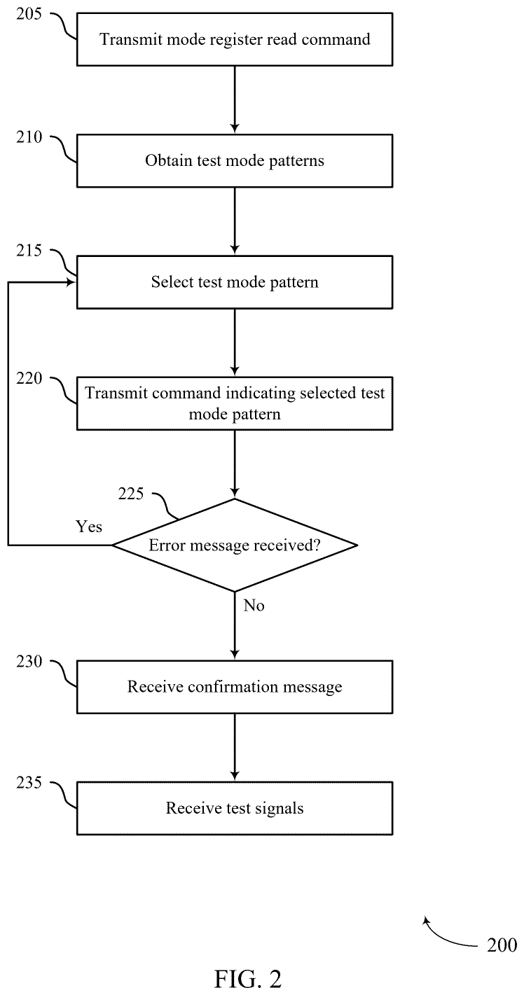

FIG. 2 shows an example of a flow diagram 200 that supports user-enabled test mode patterns in accordance with examples as disclosed herein. In some examples, the flow diagram 200 may implement or be implemented by aspects of the system 100. For example, the flow diagram 200 may be implemented by a host system 105, which may be an example of the host system 105 as illustrated by and described with reference to FIG. 1. For example, the flow diagram 200 may be implemented by the host system controller 106 and/or one or more additional components of the host system.

Alternative examples of the following may be implemented. Some operations may be performed in a different order than described or are not performed at all. In some cases, operations may include additional features not mentioned below, or further operations may be added. Although the host system 105 (e.g., via the host system controller 106) is described as performing the operations of the flow diagram 200, some aspects of some operations may also be performed by one or more other systems or devices.

At 205, the host system 105 may transmit a mode register read command. For example, the host system 105 may transmit a mode register read command to obtain, at 210, multiple test mode patterns from a mode register of the memory system 110. In other words, the host system 105 may read a mode register to obtain the multiple test mode patterns from the memory system 110. The multiple test mode patterns may be patterns supported by the memory system 110. For example, the mode register may include a CJTPAT, CRPAT, or the like.

At 215, the host system 105 may select a test mode pattern. For example, the host system 105 may select a test mode pattern of the multiple test mode patterns. In some examples, selecting the first test mode pattern from the multiple test mode patterns may be in accordance with transmitting the mode register read command at 205. That is, the host system 105 may select the test mode pattern from the test mode patterns supported by the memory system 110 (e.g., obtained at 210 by reading the mode register). As described herein, the host system 105 and the memory system 110 may utilize the test pattern to obtain transmitter measurements, e.g., rise and fall times, where the test patterns may include a single repeated 10-bit code word. Additionally, the memory system 110 and the host system 105 may utilize one or more other test patterns, such as CJTPAT and CRPAT, to obtain other measurements, such as transmitter jitter. In such examples, the test pattern may provide worst case results, while conforming to 8b 10b coding rules.

In some examples, the host system 105 may select one or more parameters in addition to the test mode pattern. For example, the host system 105 may select a set of (e.g., multiple) parameters, where the set of parameters includes the test mode pattern and additional parameters associated with transmission of test signals by the memory system 110. In some examples, the host system 105 may select the set of parameters based on reading a mode register of the memory system 110 (e.g., a same or different mode register than the mode register read at 210) that identifies capabilities of the memory system 110 associated with each parameter. That is, the mode register may include capabilities associated with speed modes (e.g., high speed (HS), low speed (LS), etc.) for transmission of test signals, gear parameters (e.g., Gear1, Gear2, Gear3, Gear4, Gear5), rate parameters (e.g., A or B), clock frequencies (e.g., 19.2 MHZ, 26 MHz, 38.4 MHZ, or 52 MHZ), transmission modes (e.g., burst, continuous, etc.), lanes (e.g., Lane0, Lane1, or both), hold-off times, scrambling modes (e.g., on or off), time durations (e.g., how long the transmission of the test pattern may occur), and passwords. Such parameters may be further described herein with reference to the operations at 220. In some examples, the host system 105 may select the test mode pattern based on one or more selected parameters. As an illustrative example, the host system 105 may determine a quantity of lanes associated with transmission of the test signals, and based on the quantity of lanes, may select one of the multiple test patterns. In such examples, if multiple lanes are utilized, either the same time-shifted pattern, or different patterns, can be used for individual lanes (e.g., the host system 105 may utilize a same or different test pattern over each lane).

At 220, the host system 105 may transmit a command indicating the selected test mode pattern. For example, the host system 105 may transmit a command to transmit multiple test signals. The command may include the set of parameters associated with transmission of the multiple test signals. The set of parameters may include an indication of the test mode pattern of the multiple test mode patterns (e.g., selected at 215) for transmission of the multiple test signals and a first time duration associated with transmission of the multiple test signals.

The set of parameters may include, in addition to the test mode pattern, an indication of a speed mode for transmission of the multiple test signals. For example, the speed mode may be HS or LS, among other examples. The different speed modes may be examples of different signaling schemes. For example, the HS mode may support multiple gears (e.g., the multiple gears of Table 1), while the LS mode may correspond to a pulse width modulation (PWM) signaling scheme supporting a first gear (e.g., a single gear). Gears, as referenced herein, may generally correspond to different data rates based on one or more other parameters, including a rate parameter, a clock frequency, or the like.

For example, the set of parameters may include, in addition to the test mode pattern, a gear parameter, a rate parameter, a clock frequency, or any combination thereof that correspond to a data rate associated with transmission of the multiple test signals. Different combinations of gear parameters, rate parameters, and clock frequencies may correspond to different data rates relative to a reference frequency f_{ref} according to Table 1 below, as an example.

TABLE 1

| | Rate A | Rate B | | |
|---|---|---|---|---|
| Gear | f_{ref} | f_{ref} | | Unit |
| | 19.2/26.0/38.4/52.0 | 19.2/38.4 | 26.0/52.0 | MHz |
| GEAR1 | 1248 | 1459.2 | 1456.0 | Mbps |
| GEAR2 | 2496 | 2918.4 | 2912.0 | Mbps |
| GEAR3 | 4992 | 5836.8 | 5824.0 | Mbps |
| GEAR4 | 9984 | 11673.6 | 11648.0 | Mbps |
| GEAR5 | 19968 | 23347.2 | 23296.0 | Mbps |

In the example of Table 1, the gear parameters may correspond to HS gear parameters. For example, the host system 105 may indicate the gear parameter, rate parameter, and clock frequency in examples in which the speed mode is HS. In examples in which the speed mode is in LS, the set of parameters may not include a gear parameter. That is, because the LS mode may support the first gear (e.g., GEAR1), the host system 105 may reduce overhead by not including the gear in the set of parameters indicated to the memory system 110.

The set of parameters may include, in addition to the test mode pattern, an indication whether to transmit the multiple test signals according to a burst mode of operation or a continuous mode of operation. For example, the burst mode of operation may include first periods in time in which the memory system 110 transmits the test signals and second periods in time in which the memory system 110 does not transmit the test signals (e.g., where the second periods are longer than the first periods). That is, the burst mode of operation may include at least two bit rates (e.g., a nonzero bit rate and a zero bit rate) corresponding to the first periods in time and the second periods in time. Alternatively, the continuous mode may include a constant bit rate at which the memory system 110 transmits the test signals (e.g., without periods in which the test signals are not transmitted).

In some examples, the set of parameters may include, in addition to the test mode pattern, an indication of one or more lanes. For example, the memory system 110 may support a first lane, a second lane, or both. The lanes may be examples of lanes in which a physical signal may be transmitted. The lanes may be examples of upstream lanes, downstream lanes, or both. Additionally, or alternatively, the set of parameters may include an indication of whether to scramble the plurality of test signals. That is, the set of parameters may include an indication of whether scrambling is on (e.g., scrambling performed) or off (e.g., scrambling not performed). The set of parameters may include, in addition to the test mode pattern, a password associated with enabling transmission of the plurality of test signals. For example, the set of parameters may include the password such that the test mode is not enabled involuntarily. That is, the memory system 110 may store a password associated with enablement of the test mode, where the host system 105 may provide the password in the set of parameters in order to enable the test mode.

Additionally, or alternatively, the set of parameters may include a first time duration (e.g., Time Duration) and a second time duration (e.g., Hold-off time). The first time duration may be an amount of time over or during which the memory system 110 transmits the test signals or the host system 105 receives the test signals (e.g., at 235). In other words, the first time duration may be between a start of communication of the test signals (e.g., transmission by the memory system 110 or receipt by the host system 105) and an end of communication of the test signals. That is, the first time duration may be defined by a time elapsed between communication of a first test signal (e.g., in time) of the multiple test signals and a last test signal (e.g., in time) of the multiple test signals. The second time duration may correspond to an amount of time between receipt of the confirmation message by the host system 105 (e.g., at 230) and transmission of test signals by the memory system 110. In other words, the second time duration may be between the confirmation message and the test signals (e.g., a first test signal, in time, of the multiple test signals). Alternatively, the second time duration may correspond to an amount of time between transmission of the command at 220 by the host system 105 and transmission of the test signals by the memory system 110. That is, the second time duration may be between the command and the test signals (e.g., a first test signal, in time, of the multiple test signals). In some examples, the host system 105 may indicate, via the command, whether the hold-off time begins from the transmission of the command at 220 or begins from the reception of the message at 225.

As an illustrative example, the host system 105 may transmit the command (e.g., COMMAND_X), which may include the following arguments: HS, Gear=4, Rate=B, Clock=26 MHZ, Pattern=CJTPAT, Continuous, #Lanes=2, Hold-off time=30s, Scrambling=ON, Time duration=300 s, Password. In some examples, transmitting the command at 220 may be in accordance with selecting the test mode pattern at 215.

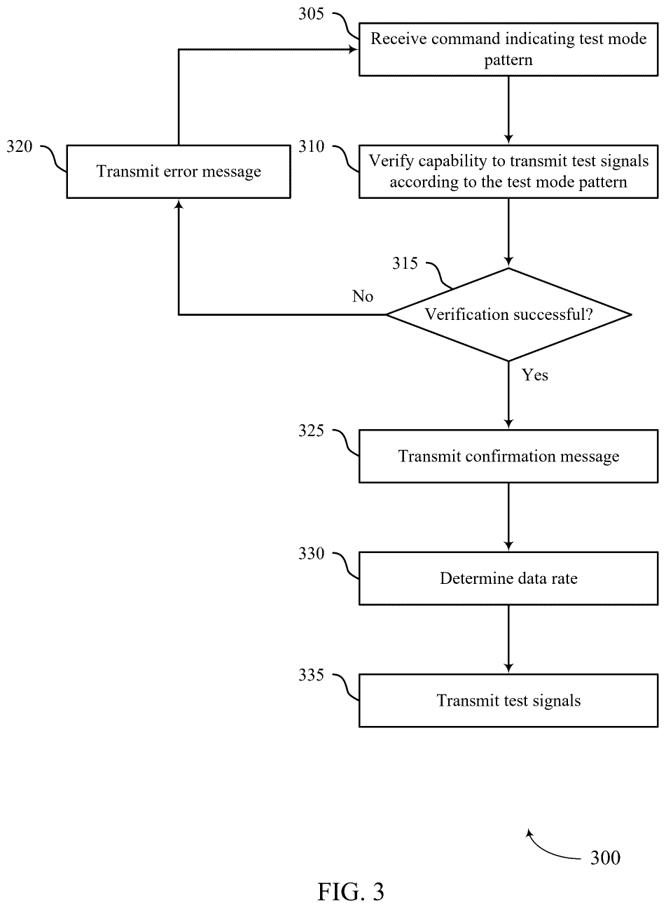

At 225, the host system 105 may determine whether an error message (e.g., an error signal) was received. That is, in some examples, the host system 105 may receive a message from the memory system 110 that indicates one or more errors associated with the set of parameters. Detection of the one or more errors by the memory system 110 may be described in greater detail elsewhere herein, including with reference to operation 310 of FIG. 3. In such examples, the host system 105 may select a new test mode pattern and transmit a command indicating the newly selected test mode pattern. In other words, the host system 105 may repeat the operations at 215 and 220 after receiving the message that indicates errors associated with a set of parameters indicated in a command (e.g., a most recently transmitted command). That is, command indicating the selected test mode pattern may be transmitted at 220 in accordance with receiving the error message at 225.

At 230, the host system 105 may receive a confirmation message. For example, the host system 105 may receive, in accordance with transmitting the command at 220 (e.g., an updated command or an initial command), a message that indicates confirmation of the set of parameters associated with transmission of the multiple test signals. That is, alternatively to receiving an error message indicating an error associated with the set of parameters, the host system 105 may receive the confirmation message confirming the set of parameters (e.g., indicating a lack of errors in the set of parameters). In some examples, receiving the message at 230 indicating the confirmation of the set of parameters may be in accordance with the password (e.g., included in the set of parameters) being equivalent to the password stored at the memory system 110. That is, the memory system 110 may confirm the parameters with the host system 105 (e.g., transmit the confirmation message) based on the host system 105 providing a correct password.

At 235, the host system 105 may receive test signals. For example, the host system 105 may receive, during the first time duration, the multiple test signals in accordance with the test mode pattern and with receiving the message at 230. That is, the host system 105 may receive the test signals in accordance with the set of parameters, including the test mode pattern, confirmed via the confirmation message at 230. For example, the test signals may be in accordance with the speed mode, the data rate (e.g., corresponding to the gear parameter, rate parameter, clock frequency, or a combination), the burst or continuous mode, or any combination thereof. Additionally, or alternatively, the test signals may be received after the second time duration from reception of the confirmation message at 230 or transmission of the command at 220. The host system 105 may perform measurements, validation, or both for the test signals during the first time duration (e.g., while the test signals are communicated).

The host system 105, the memory system 110, or both may exit the test mode (e.g., stop communicating the test signals). In some examples, the host system 105 may exit the test mode based on the first time duration elapsing or expiring. Alternatively, the host system 105 may exit the test mode based on a power cycle or a hardware reset. For example, the host system 105 may exit the test mode based on a device of the host system 105 being turned off or based on one or more hardware components of the device including the host system 105 and the memory system 110 being reset.

FIG. 3 shows an example of a flow diagram 300 that supports user-enabled test mode patterns in accordance with examples as disclosed herein. In some examples, the flow diagram 300 may implement or be implemented by aspects of the system 100. For example, the flow diagram 300 may be implemented by a memory system 110 (or a memory system controller 115), which may be an example of the memory system 110 110 as illustrated by and described with reference to FIG. 1. The memory system 110 may be an example of or otherwise include an mNAND or a UFS.

Alternative examples of the following may be implemented. Some operations may be performed in a different order than described or are not performed at all. In some cases, operations may include additional features not mentioned below, or further operations may be added. Although the memory system 110 is described as performing the operations of the flow diagram 300, some aspects of some operations may also be performed by one or more other systems or devices, such as the memory system controller 115.

At 305, the memory system 110 may receive a command indicating a test mode pattern. For example, the memory system 110 may receive a command to transmit multiple test signals, the command including a set of parameters associated with transmission of the multiple test signals. The set of parameters may include an indication of a test mode pattern of multiple test mode patterns for transmission of the multiple test signals and a first time duration (e.g., a first duration, period, time, range, or the like) associated with transmission of the multiple test signals. For example, the test mode pattern may be one of multiple test mode patterns supported by the memory system 110. In some examples, the multiple test mode patterns supported by the memory system 110 may be stored at a mode register of the memory system 110. The set of parameters may include a speed mode (e.g., HS or LS); a gear parameter, a rate parameter, and a clock frequency (e.g., corresponding to a data rate, such as according to Table 1); an operation mode (e.g., burst mode or continuous mode); one or more lanes; a first time duration; a second time duration; a scrambling mode; a password; or any combination thereof. The set of parameters may be described in greater detail elsewhere herein, including with reference to FIG. 2.

At 310, the memory system 110 may verify a capability to transmit test signals according to the test mode pattern. For example, the memory system 110 may verify whether the memory system 110 is capable of transmitting the multiple test signals in accordance with the set of parameters (e.g., in the command received at 305). At 315, the memory system 110 may determine whether the verification was successful. In examples in which the verification is not successful, at 320, the memory system 110 may transmit an error message. For example, the memory system 110 may transmit a message that indicates one or more errors associated with the set of parameters in accordance with the memory system 110 being incapable of transmitting the multiple test signals in accordance with the set of parameters. As an illustrative example, the memory system 110 may transmit a message that identifies which parameters, of the set of parameters, are in error. Alternatively, the memory system 110 may transmit, via the message, an indication that the command is invalid, without providing detailed indications of which parameters may be incorrect. The memory system 110 may receive an updated command at 305 based on transmitting the error message. In other words, the memory system 110 may receive a command at 305 including an updated set of parameters (e.g., correcting the reported errors) in accordance with transmitting the error message.

In examples in which the verification is successful (e.g., for the initial command or an updated command), at 325, the memory system 110 may transmit a confirmation message. For example, the memory system 110 may transmit, in accordance with receiving the command at 305, a message that indicates confirmation of the set of parameters (e.g., the original or updated parameters) associated with transmission of the multiple test signals. The memory system 110 may transmit the confirmation message in accordance with verifying the capability of the memory system 110 to transmit the test signals according to the indicated test mode pattern (e.g., and the other parameters of the set of parameters). In some examples, transmitting the message confirming the set of parameters may be in accordance with verifying that the memory system 110 is capable of transmitting the multiple test signals in accordance with the first set of parameters at 310. Additionally, or alternatively, transmitting the message confirming the set of parameters may activate a test mode at the memory system 110.

At 330, the memory system 110 may determine a data rate. For example, the memory system 110 may determine a data rate associated with transmission of the multiple test signals in accordance with the gear parameter, the rate parameter, the clock frequency, or any combination thereof. Determining the data rate may be based on a table including entries corresponding to different combinations of gear parameters, rate parameters, and clock frequencies, such as Table 1 as described with reference to FIG. 2.

At 335, the memory system 110 may transmit test signals. For example, the memory system 110 may transmit, during the first time duration, the multiple test signals in accordance with the test mode pattern and with transmitting the message at 325. Additionally, the memory system 110 may transmit the multiple test signals in accordance with the set of parameters, such as in accordance with the speed mode, the data rate (e.g., corresponding to the gear parameter, rate parameter, and clock frequency), the operation mode, the one or more lanes, the first time duration, the second time duration, the scrambling mode, the password, or any combination thereof. For example, the memory system 110 may transmit the test signals after the second time duration from transmission of the confirmation message at 325 or reception of the command at 305. The memory system 110 may transmit the test signals for the first time duration (e.g., included in the set of parameters). After the first time duration, the test mode (e.g., activated after transmission of the confirmation message at 325) may be deactivated. Similarly, if the memory system 110 experiences a power cycle or hardware reset, the test mode may be deactivated and the memory system 110 may exit the test mode.

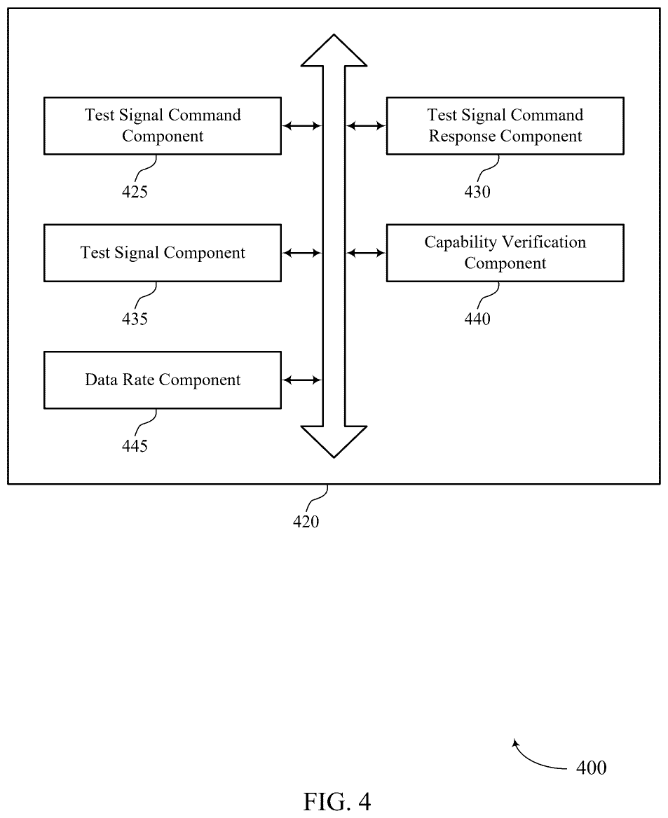

FIG. 4 shows a block diagram 400 of a memory system 420 that supports user-enabled test mode patterns in accordance with examples as disclosed herein. The memory system 420 may be an example of aspects of a memory system as described with reference to FIGS. 1 through 3. The memory system 420, or various components thereof, may be an example of means for performing various aspects of user-enabled test mode patterns as described herein. For example, the memory system 420 may include a test signal command component 425, a test signal command response component 430, a test signal component 435, a capability verification component 440, a data rate component 445, or any combination thereof. Each of these components, or components of subcomponents thereof (e.g., one or more processors, one or more memories), may communicate, directly or indirectly, with one another (e.g., via one or more buses).

The memory system 420 may support operating a memory system in accordance with examples as disclosed herein. The test signal command component 425 may be configured as or otherwise support a means for receiving a command to transmit a plurality of test signals, the command including a first set of parameters associated with transmission of the plurality of test signals, where the first set of parameters include an indication of a first test mode pattern of a plurality of test mode patterns for transmission of the plurality of test signals and a first time duration associated with transmission of the plurality of test signals. The test signal command response component 430 may be configured as or otherwise support a means for transmitting, in accordance with receiving the command, a message that indicates confirmation of the first set of parameters associated with transmission of the plurality of test signals. The test signal component 435 may be configured as or otherwise support a means for transmitting, during the first time duration, the plurality of test signals in accordance with the first test mode pattern and with transmitting the message.

In some examples, the capability verification component 440 may be configured as or otherwise support a means for verifying whether the memory system is capable of transmitting the plurality of test signals in accordance with the first set of parameters, where transmitting the message confirming the first set of parameters is in accordance with verifying that the memory system is capable of transmitting the plurality of test signals in accordance with the first set of parameters.

In some examples, the test signal command component 425 may be configured as or otherwise support a means for receiving, prior to receiving the command, a second command to transmit the plurality of test signals, the command including a second set of parameters associated with transmission of the plurality of test signals. In some examples, the capability verification component 440 may be configured as or otherwise support a means for verifying whether the memory system is capable of transmitting the plurality of test signals in accordance with the second set of parameters. In some examples, the test signal command response component 430 may be configured as or otherwise support a means for transmitting a second message that indicates one or more errors associated with the second set of parameters in accordance with the memory system being incapable of transmitting the plurality of test signals in accordance with the second set of parameters, where the command including the first set of parameters is received in accordance with transmitting the second message.

In some examples, the first set of parameters further include an indication of a speed mode for transmission of the plurality of test signals. In some examples, transmitting the plurality of test signals is further in accordance with the speed mode.

In some examples, the first set of parameters further include a gear parameter, and the data rate component 445 may be configured as or otherwise support a means for determining a data rate associated with transmission of the plurality of test signals in accordance with the gear parameter, the rate parameter, the clock frequency, or any combination thereof, where transmitting the plurality of test signals is further in accordance with the data rate.

In some examples, the first set of parameters further include an indication whether to transmit the plurality of test signals according to a burst mode of operation or a continuous mode of operation. In some examples, the plurality of test signals are transmitted in accordance with the indication.

In some examples, the first set of parameters further include an indication of one or more lanes to be used for transmission of the plurality of test signals. In some examples, the plurality of test signals are transmitted via the one or more lanes.

In some examples, to support transmitting the plurality of test signals, the test signal component 435 may be configured as or otherwise support a means for transmitting, after the second time duration from transmission of the message, the plurality of test signals in accordance with the first test mode pattern. In some examples, to support transmitting the plurality of test signals, the test signal component 435 may be configured as or otherwise support a means for transmitting, after the second time duration from reception of the command, the plurality of test signals in accordance with the first test mode pattern.

In some examples, the first set of parameters further include an indication of whether to scramble the plurality of test signals. In some examples, transmitting the plurality of test signals is further in accordance with the indication.

In some examples, the first set of parameters further include a password associated with enabling transmission of the plurality of test signals. In some examples, confirming the first set of parameters is in accordance with the password indicated via the command being equivalent to a second password stored at the memory system.

In some examples, transmission of the message activates a test mode at the memory system. In some examples, the test mode is deactivated after the first time duration.

In some examples, the described functionality of the memory system 420, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 420, or various components thereof, may be implemented at least in part by instructions (e.g., stored in memory, non-transitory computer-readable medium) executable by such at least one processor.

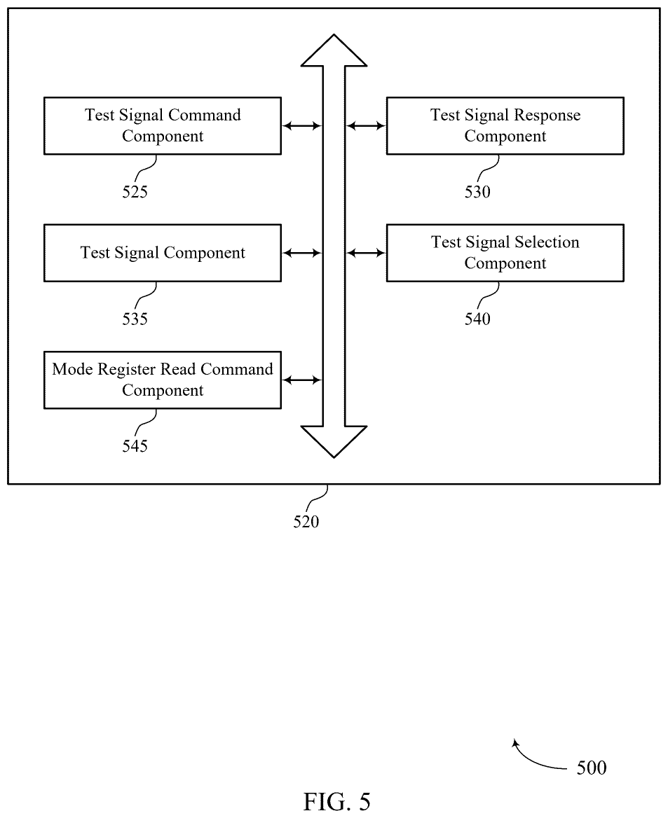

FIG. 5 shows a block diagram 500 of a host system 520 that supports user-enabled test mode patterns in accordance with examples as disclosed herein. The host system 520 may be an example of aspects of a host system as described with reference to FIGS. 1 through 3. The host system 520, or various components thereof, may be an example of means for performing various aspects of user-enabled test mode patterns as described herein. For example, the host system 520 may include a test signal command component 525, a test signal response component 530, a test signal component 535, a test signal selection component 540, a mode register read command component 545, or any combination thereof. Each of these components, or components of subcomponents thereof (e.g., one or more processors, one or more memories), may communicate, directly or indirectly, with one another (e.g., via one or more buses).

The host system 520 may support operating a host system in accordance with examples as disclosed herein. The test signal command component 525 may be configured as or otherwise support a means for transmitting, to a memory system, a command to transmit a plurality of test signals, the command including a first set of parameters associated with transmission of the plurality of test signals, where the first set of parameters include an indication of a first test mode pattern of a plurality of test mode patterns for transmission of the plurality of test signals and a first time duration associated with transmission of the plurality of test signals. The test signal response component 530 may be configured as or otherwise support a means for receiving, in accordance with transmitting the command, a message that indicates confirmation of the first set of parameters associated with transmission of the plurality of test signals. The test signal component 535 may be configured as or otherwise support a means for receiving, during the first time duration, the plurality of test signals in accordance with the first test mode pattern and with receiving the message.

In some examples, the test signal selection component 540 may be configured as or otherwise support a means for selecting the first test mode pattern of the plurality of test mode patterns, where transmitting the command is in accordance with selecting the first test mode pattern.

In some examples, the mode register read command component 545 may be configured as or otherwise support a means for transmitting a mode register read command to obtain the plurality of test mode patterns from a mode register of the memory system, where selecting the first test mode pattern from the plurality of test mode patterns is in accordance with transmitting the mode register read command.

In some examples, the test signal command component 525 may be configured as or otherwise support a means for transmitting, prior to transmitting the command, a second command to transmit the plurality of test signals, the command including a second set of parameters associated with transmission of the plurality of test signals. In some examples, the test signal response component 530 may be configured as or otherwise support a means for receiving a second message that indicates one or more errors associated with the second set of parameters, where the command including the first set of parameters is transmitted in accordance with receiving the second message.

In some examples, the first set of parameters further include an indication of a speed mode for transmission of the plurality of test signals. In some examples, receiving the plurality of test signals is further in accordance with the speed mode.

In some examples, the first set of parameters further include a gear parameter, a rate parameter, a clock frequency, or any combination thereof, that correspond to a data rate associated with transmission of the plurality of test signals. In some examples, receiving the plurality of test signals is further in accordance with the data rate.

In some examples, the first set of parameters further include an indication whether to transmit the plurality of test signals according to a burst mode of operation or a continuous mode of operation. In some examples, the plurality of test signals are transmitted in accordance with the indication.

In some examples, the first set of parameters further include an indication of one or more lanes. In some examples, the plurality of test signals are received via the one or more lanes.

In some examples, to support receiving the plurality of test signals, the test signal component 535 may be configured as or otherwise support a means for receiving, after the second time duration from reception of the message, the plurality of test signals in accordance with the first test mode pattern. In some examples, to support receiving the plurality of test signals, the test signal component 535 may be configured as or otherwise support a means for receiving, after the second time duration from transmission of the command, the plurality of test signals in accordance with the first test mode pattern.

In some examples, the first set of parameters further include an indication of whether to scramble the plurality of test signals. In some examples, receiving the plurality of test signals is further in accordance with the indication.

In some examples, the first set of parameters further include a password associated with enabling transmission of the plurality of test signals. In some examples, receiving the message indicating the confirmation of the first set of parameters is in accordance with the password being equivalent to a second password stored at the memory system.

In some examples, the described functionality of the host system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the host system 520, or various components thereof, may be implemented at least in part by instructions (e.g., stored in memory, non-transitory computer-readable medium) executable by such at least one processor.

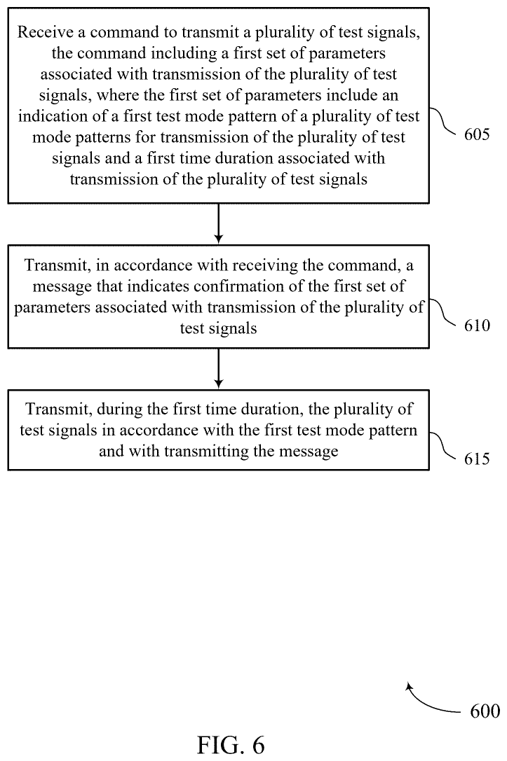

FIG. 6 shows a flowchart illustrating a method 600 that supports user-enabled test mode patterns in accordance with examples as disclosed herein. The operations of method 600 may be implemented by a memory system or its components as described herein. For example, the operations of method 600 may be performed by a memory system as described with reference to FIGS. 1 through 4. In some examples, a memory system may execute a set of instructions to control the functional elements of the device to perform the described functions. Additionally, or alternatively, the memory system may perform aspects of the described functions using special-purpose hardware.

At 605, the method may include receiving a command to transmit a plurality of test signals, the command including a first set of parameters associated with transmission of the plurality of test signals, where the first set of parameters include an indication of a first test mode pattern of a plurality of test mode patterns for transmission of the plurality of test signals and a first time duration associated with transmission of the plurality of test signals. In some examples, aspects of the operations of 605 may be performed by a test signal command component 425 as described with reference to FIG. 4 that receives test signal commands at the memory device—e.g., as described herein, including with reference to the operations described at 305 of FIG. 3.

At 610, the method may include transmitting, in accordance with receiving the command, a message that indicates confirmation of the first set of parameters associated with transmission of the plurality of test signals. In some examples, aspects of the operations of 610 may be performed by a test signal command response component 430 as described with reference to FIG. 4 that transmits test signal command responses at the memory device—e.g., as described herein, including with reference to the operations described at 325 of FIG. 3.

At 615, the method may include transmitting, during the first time duration, the plurality of test signals in accordance with the first test mode pattern and with transmitting the message. In some examples, aspects of the operations of 615 may be performed by a test signal component 435 as described with reference to FIG. 4 that transmits test signal commands at the memory device—e.g., as described herein, including with reference to the operations described at 335 of FIG. 3.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a command to transmit a plurality of test signals, the command including a first set of parameters associated with transmission of the plurality of test signals, where the first set of parameters include an indication of a first test mode pattern of a plurality of test mode patterns for transmission of the plurality of test signals and a first time duration associated with transmission of the plurality of test signals; transmitting, in accordance with receiving the command, a message that indicates confirmation of the first set of parameters associated with transmission of the plurality of test signals; and transmitting, during the first time duration, the plurality of test signals in accordance with the first test mode pattern and with transmitting the message.

Aspect 2: The method, apparatus, or non-transitory computer-readable medium of aspect 1, further including operations, features, circuitry, logic, means, or instructions, or any combination thereof for verifying whether the memory system is capable of transmitting the plurality of test signals in accordance with the first set of parameters, where transmitting the message confirming the first set of parameters is in accordance with verifying that the memory system is capable of transmitting the plurality of test signals in accordance with the first set of parameters.

Aspect 3: The method, apparatus, or non-transitory computer-readable medium of any of aspects 1 through 2, further including operations, features, circuitry, logic, means, or instructions, or any combination thereof for receiving, prior to receiving the command, a second command to transmit the plurality of test signals, the command including a second set of parameters associated with transmission of the plurality of test signals; verifying whether the memory system is capable of transmitting the plurality of test signals in accordance with the second set of parameters; and transmitting a second message that indicates one or more errors associated with the second set of parameters in accordance with the memory system being incapable of transmitting the plurality of test signals in accordance with the second set of parameters, where the command including the first set of parameters is received in accordance with transmitting the second message.

Aspect 4: The method, apparatus, or non-transitory computer-readable medium of any of aspects 1 through 3, where the first set of parameters further include an indication of a speed mode for transmission of the plurality of test signals and transmitting the plurality of test signals is further in accordance with the speed mode.

Aspect 5: The method, apparatus, or non-transitory computer-readable medium of any of aspects 1 through 4, where the first set of parameters further include a gear parameter and the method, apparatuses, and non-transitory computer-readable medium further includes operations, features, circuitry, logic, means, or instructions, or any combination thereof for determining a data rate associated with transmission of the plurality of test signals in accordance with the gear parameter, the rate parameter, the clock frequency, or any combination thereof, where transmitting the plurality of test signals is further in accordance with the data rate.

Aspect 6: The method, apparatus, or non-transitory computer-readable medium of any of aspects 1 through 5, where the first set of parameters further include an indication whether to transmit the plurality of test signals according to a burst mode of operation or a continuous mode of operation and the plurality of test signals are transmitted in accordance with the indication.

Aspect 7: The method, apparatus, or non-transitory computer-readable medium of any of aspects 1 through 6, where the first set of parameters further include an indication of one or more lanes to be used for transmission of the plurality of test signals and the plurality of test signals are transmitted via the one or more lanes.

Aspect 8: The method, apparatus, or non-transitory computer-readable medium of any of aspects 1 through 7, where transmitting the plurality of test signals further includes operations, features, circuitry, logic, means, or instructions, or any combination thereof for transmitting, after the second time duration from transmission of the message, the plurality of test signals in accordance with the first test mode pattern and transmitting, after the second time duration from reception of the command, the plurality of test signals in accordance with the first test mode pattern.

Aspect 9: The method, apparatus, or non-transitory computer-readable medium of any of aspects 1 through 8, where the first set of parameters further include an indication of whether to scramble the plurality of test signals and transmitting the plurality of test signals is further in accordance with the indication.

Aspect 10: The method, apparatus, or non-transitory computer-readable medium of any of aspects 1 through 9, where the first set of parameters further include a password associated with enabling transmission of the plurality of test signals and confirming the first set of parameters is in accordance with the password indicated via the command being equivalent to a second password stored at the memory system.

Aspect 11: The method, apparatus, or non-transitory computer-readable medium of any of aspects 1 through 10, where transmission of the message activates a test mode at the memory system and the test mode is deactivated after the first time duration.

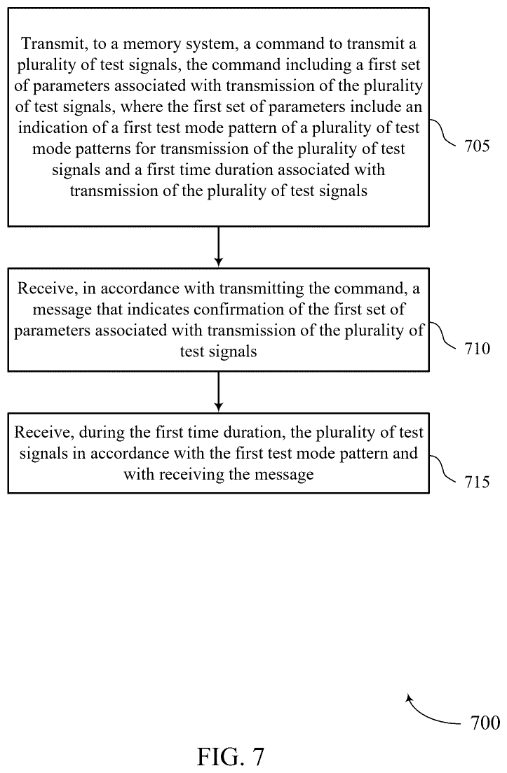

FIG. 7 shows a flowchart illustrating a method 700 that supports user-enabled test mode patterns in accordance with examples as disclosed herein. The operations of method 700 may be implemented by a host system or its components as described herein. For example, the operations of method 700 may be performed by a host system as described with reference to FIGS. 1 through 3 and 5. In some examples, a host system may execute a set of instructions to control the functional elements of the device to perform the described functions. Additionally, or alternatively, the host system may perform aspects of the described functions using special-purpose hardware.

At 705, the method may include transmitting, to a memory system, a command to transmit a plurality of test signals, the command including a first set of parameters associated with transmission of the plurality of test signals, where the first set of parameters include an indication of a first test mode pattern of a plurality of test mode patterns for transmission of the plurality of test signals and a first time duration associated with transmission of the plurality of test signals. In some examples, aspects of the operations of 705 may be performed by a test signal command component 525 as described with reference to FIG. 5 that transmits test signal commands at the host device—e.g., as described herein, including with reference to the operations described at 220 of FIG. 2.

At 710, the method may include receiving, in accordance with transmitting the command, a message that indicates confirmation of the first set of parameters associated with transmission of the plurality of test signals. In some examples, aspects of the operations of 710 may be performed by a test signal response component 530 as described with reference to FIG. 5 that receives test signal command responses at the host device—e.g., as described herein, including with reference to the operations described at 230 of FIG. 2.

At 715, the method may include receiving, during the first time duration, the plurality of test signals in accordance with the first test mode pattern and with receiving the message. In some examples, aspects of the operations of 715 may be performed by a test signal component 535 as described with reference to FIG. 5 that receives test signals at the host device—e.g., as described herein, including with reference to the operations described at 235 of FIG. 2.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 12: A method, apparatus, or non-transitory computer-readable medium including operations, features, circuitry, logic, means, or instructions, or any combination thereof for transmitting, to a memory system, a command to transmit a plurality of test signals, the command including a first set of parameters associated with transmission of the plurality of test signals, where the first set of parameters include an indication of a first test mode pattern of a plurality of test mode patterns for transmission of the plurality of test signals and a first time duration associated with transmission of the plurality of test signals; receiving, in accordance with transmitting the command, a message that indicates confirmation of the first set of parameters associated with transmission of the plurality of test signals; and receiving, during the first time duration, the plurality of test signals in accordance with the first test mode pattern and with receiving the message.

Aspect 13: The method, apparatus, or non-transitory computer-readable medium of aspect 12, further including operations, features, circuitry, logic, means, or instructions, or any combination thereof for selecting the first test mode pattern of the plurality of test mode patterns, where transmitting the command is in accordance with selecting the first test mode pattern.

Aspect 14: The method, apparatus, or non-transitory computer-readable medium of aspect 13, further including operations, features, circuitry, logic, means, or instructions, or any combination thereof for transmitting a mode register read command to obtain the plurality of test mode patterns from a mode register of the memory system, where selecting the first test mode pattern from the plurality of test mode patterns is in accordance with transmitting the mode register read command.

Aspect 15: The method, apparatus, or non-transitory computer-readable medium of any of aspects 12 through 14, further including operations, features, circuitry, logic, means, or instructions, or any combination thereof for transmitting, prior to transmitting the command, a second command to transmit the plurality of test signals, the command including a second set of parameters associated with transmission of the plurality of test signals and receiving a second message that indicates one or more errors associated with the second set of parameters, where the command including the first set of parameters is transmitted in accordance with receiving the second message.

Aspect 16: The method, apparatus, or non-transitory computer-readable medium of any of aspects 12 through 15, where the first set of parameters further include an indication of a speed mode for transmission of the plurality of test signals and receiving the plurality of test signals is further in accordance with the speed mode.

Aspect 17: The method, apparatus, or non-transitory computer-readable medium of any of aspects 12 through 16, where the first set of parameters further include a gear parameter, a rate parameter, a clock frequency, or any combination thereof, that correspond to a data rate associated with transmission of the plurality of test signals and receiving the plurality of test signals is further in accordance with the data rate.

Aspect 18: The method, apparatus, or non-transitory computer-readable medium of any of aspects 12 through 17, where the first set of parameters further include an indication whether to transmit the plurality of test signals according to a burst mode of operation or a continuous mode of operation and the plurality of test signals are transmitted in accordance with the indication.

Aspect 19: The method, apparatus, or non-transitory computer-readable medium of any of aspects 12 through 18, where the first set of parameters further include an indication of one or more lanes and the plurality of test signals are received via the one or more lanes.

Aspect 20: The method, apparatus, or non-transitory computer-readable medium of any of aspects 12 through 19, where receiving the plurality of test signals further includes operations, features, circuitry, logic, means, or instructions, or any combination thereof for receiving, after the second time duration from reception of the message, the plurality of test signals in accordance with the first test mode pattern and receiving, after the second time duration from transmission of the command, the plurality of test signals in accordance with the first test mode pattern.

Aspect 21: The method, apparatus, or non-transitory computer-readable medium of any of aspects 12 through 20, where the first set of parameters further include an indication of whether to scramble the plurality of test signals and receiving the plurality of test signals is further in accordance with the indication.

Aspect 22: The method, apparatus, or non-transitory computer-readable medium of any of aspects 12 through 21, where the first set of parameters further include a password associated with enabling transmission of the plurality of test signals and receiving the message indicating the confirmation of the first set of parameters is in accordance with the password being equivalent to a second password stored at the memory system.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

Additionally, the terms “directly in response to” or “in direct response to” may refer to one condition or action occurring as a direct result of a previous condition or action. In some examples, a first condition or action may be performed, and a second condition or action may occur directly as a result of the previous condition or action occurring independent of whether other conditions or actions occur. In some examples, a first condition or action may be performed, and a second condition or action may occur directly as a result of the previous condition or action occurring, such that no other intermediate conditions or actions occur between the earlier condition or action and the second condition or action or a limited quantity of one or more intermediate steps or actions occur between the earlier condition or action and the second condition or action. Any condition or action described herein as being performed “based on,” “based at least in part on,” or “in response to” some other step, action, event, or condition may additionally, or alternatively, (e.g., in an alternative example), be performed “in direct response to” or “directly in response to” such other condition or action unless otherwise specified.

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. An apparatus for operating a memory system, comprising:
processing circuitry associated with one or more memory devices and configured to cause the apparatus to:
receive a command to transmit a plurality of test signals, the command comprising a first set of parameters associated with transmission of the plurality of test signals, wherein the first set of parameters comprise an indication of a first test mode pattern of a plurality of test mode patterns for transmission of the plurality of test signals and a first time duration associated with transmission of the plurality of test signals;
transmit, in accordance with receiving the command, a message that indicates confirmation of the first set of parameters associated with transmission of the plurality of test signals; and
transmit, during the first time duration, the plurality of test signals in accordance with the first test mode pattern and with transmitting the message.

2. The apparatus of claim 1, wherein the processing circuitry is further configured to cause the apparatus to:
verify whether the memory system is capable of transmitting the plurality of test signals in accordance with the first set of parameters, wherein transmitting the message confirming the first set of parameters is in accordance with verifying that the memory system is capable of transmitting the plurality of test signals in accordance with the first set of parameters.

3. The apparatus of claim 1, wherein the processing circuitry is further configured to cause the apparatus to:
receive, prior to receiving the command, a second command to transmit the plurality of test signals, the command comprising a second set of parameters associated with transmission of the plurality of test signals;
verify whether the memory system is capable of transmitting the plurality of test signals in accordance with the second set of parameters; and
transmit a second message that indicates one or more errors associated with the second set of parameters in accordance with the memory system being incapable of transmitting the plurality of test signals in accordance with the second set of parameters, wherein the command comprising the first set of parameters is received in accordance with transmitting the second message.

4. The apparatus of claim 1, wherein the first set of parameters further comprise an indication of a speed mode for transmission of the plurality of test signals, and transmitting the plurality of test signals is further in accordance with the speed mode.

5. The apparatus of claim 1, wherein the first set of parameters further comprise a gear parameter, a rate parameter, a clock frequency, or any combination thereof, and the processing circuitry is further configured to cause the apparatus to:
determine a data rate associated with transmission of the plurality of test signals in accordance with the gear parameter, the rate parameter, the clock frequency, or any combination thereof, wherein transmitting the plurality of test signals is further in accordance with the data rate.

6. The apparatus of claim 1, wherein the first set of parameters further comprise an indication whether to transmit the plurality of test signals according to a burst mode of operation or a continuous mode of operation, and the plurality of test signals are transmitted in accordance with the indication.

7. The apparatus of claim 1, wherein the first set of parameters further comprise an indication of one or more lanes to be used for transmission of the plurality of test signals, and the plurality of test signals are transmitted via the one or more lanes.

8. The apparatus of claim 1, wherein the first set of parameters further comprise an indication of a second time duration associated with delaying transmission of the plurality of test signals, and wherein transmitting the plurality of test signals further comprises the processing circuitry configured to cause the apparatus to:
transmit, after the second time duration from transmission of the message, the plurality of test signals in accordance with the first test mode pattern; or
transmit, after the second time duration from reception of the command, the plurality of test signals in accordance with the first test mode pattern.

9. The apparatus of claim 1, wherein the first set of parameters further comprise an indication of whether to scramble the plurality of test signals, and transmitting the plurality of test signals is further in accordance with the indication.

10. The apparatus of claim 1, wherein the first set of parameters further comprise a password associated with enabling transmission of the plurality of test signals, and confirming the first set of parameters is in accordance with the password indicated via the command being equivalent to a second password stored at the memory system.

11. The apparatus of claim 1, wherein transmission of the message activates a test mode at the memory system, and the test mode is deactivated after the first time duration.

12. An apparatus for operating a host system, comprising:
processing circuitry associated with one or more memory devices and configured to cause the apparatus to:
transmit, to a memory system, a command to transmit a plurality of test signals, the command comprising a first set of parameters associated with transmission of the plurality of test signals, wherein the first set of parameters comprise an indication of a first test mode pattern of a plurality of test mode patterns for transmission of the plurality of test signals and a first time duration associated with transmission of the plurality of test signals;
receive, in accordance with transmitting the command, a message that indicates confirmation of the first set of parameters associated with transmission of the plurality of test signals; and
receive, during the first time duration, the plurality of test signals in accordance with the first test mode pattern and with receiving the message.

13. The apparatus of claim 12, wherein the processing circuitry is further configured to cause the apparatus to:
select the first test mode pattern of the plurality of test mode patterns, wherein transmitting the command is in accordance with selecting the first test mode pattern.

14. The apparatus of claim 13, wherein the processing circuitry is further configured to cause the apparatus to:
transmit a mode register read command to obtain the plurality of test mode patterns from a mode register of the memory system, wherein selecting the first test mode pattern from the plurality of test mode patterns is in accordance with transmitting the mode register read command.

15. The apparatus of claim 12, wherein the processing circuitry is further configured to cause the apparatus to:
transmit, prior to transmitting the command, a second command to transmit the plurality of test signals, the command comprising a second set of parameters associated with transmission of the plurality of test signals; and
receive a second message that indicates one or more errors associated with the second set of parameters, wherein the command comprising the first set of parameters is transmitted in accordance with receiving the second message.

16. The apparatus of claim 12, wherein the first set of parameters further comprise an indication of a speed mode for transmission of the plurality of test signals, and receiving the plurality of test signals is further in accordance with the speed mode.

17. The apparatus of claim 12, wherein the first set of parameters further comprise a gear parameter, a rate parameter, a clock frequency, or any combination thereof, that correspond to a data rate associated with transmission of the plurality of test signals, and receiving the plurality of test signals is further in accordance with the data rate.

18. The apparatus of claim 12, wherein the first set of parameters further comprise an indication whether to transmit the plurality of test signals according to a burst mode of operation or a continuous mode of operation, and the plurality of test signals are transmitted in accordance with the indication.

19. The apparatus of claim 12, wherein the first set of parameters further comprise an indication of one or more lanes, and the plurality of test signals are received via the one or more lanes.

20. The apparatus of claim 12, wherein the first set of parameters further comprise an indication of a second time duration associated with delaying transmission of the plurality of test signals, and wherein receiving the plurality of test signals further comprises the processing circuitry configured to cause the apparatus to:
receive, after the second time duration from reception of the message, the plurality of test signals in accordance with the first test mode pattern; or
receive, after the second time duration from transmission of the command, the plurality of test signals in accordance with the first test mode pattern.

21. The apparatus of claim 12, wherein the first set of parameters further comprise an indication of whether to scramble the plurality of test signals, and receiving the plurality of test signals is further in accordance with the indication.

22. The apparatus of claim 12, wherein the first set of parameters further comprise a password associated with enabling transmission of the plurality of test signals, and receiving the message indicating the confirmation of the first set of parameters is in accordance with the password being equivalent to a second password stored at the memory system.

23. A method for operating a memory system, comprising:
receiving a command to transmit a plurality of test signals, the command comprising a first set of parameters associated with transmission of the plurality of test signals, wherein the first set of parameters comprise an indication of a first test mode pattern of a plurality of test mode patterns for transmission of the plurality of test signals and a first time duration associated with transmission of the plurality of test signals;
transmitting, in accordance with receiving the command, a message that indicates confirmation of the first set of parameters associated with transmission of the plurality of test signals; and
transmitting, during the first time duration, the plurality of test signals in accordance with the first test mode pattern and with transmitting the message.
